(19) United States
(12) Patent Application Publication
(10) Pub. No.: US 2007/0022351 A1
(43) Pub. Date: Jan. 25, 2007

(54) Method and apparatus that provide for configuration of hardware resources specified in a test template

(76) Inventors: Zhengrong Zhou, Santa Rose, CA (US); Ashish Desai, San Francisco, CA (US); Jason L. Smith, Santa Rosa, CA (US)

Correspondence Address: AGILENT TECHNOLOGIES INC., INTELLECTUAL PROPERTY ADMINISTRATION, M/S DU404, P.O. BOX 7599, LOVELAND, CO, 80537-0599, US

(21) Appl. No.: 11/169,541

(22) Filed: Jun. 29, 2005

(51) Int. Cl. G01R 31/28; G06F 11/00

(52) U.S. Cl. 714/744

(57) ABSTRACT

In one embodiment, the execution of instructions causes a machine to: 1) display an automated test equipment (ATE) test template selection tool; 2) upon user selection of a test template from the ATE test template selection tool, display default parameters of the selected test template; and 3) provide user access to a tool that enables a user to configure at least one hardware resource specified by the test template. In another embodiment, the execution of instructions causes a machine to A) display a tool that enables a user to configure at least one hardware resource specified by a test template for ATE; and B) upon a user's use of the tool to select a hardware resource, enable the user to configure the selected hardware resource.

### BACKGROUND

Prior to the manufacture and/or distribution of an electrical device (including a system or component such as a circuit board, integrated circuit, or system-on-a-chip (SOC)), the device is typically tested to determine whether it is built or functions as designed. Often, this testing is performed by automated test equipment (ATE, also called “testers”).

Prior to using ATE to test a device, a test developer must develop the series of tests that the ATE will execute while testing the device. Historically, this has been done on a custom basis for each device that ATE is to test. While a test developer has a great deal of latitude when developing custom tests, this is a costly and time-intensive process that can add a significant amount of delay to a device's “time to market” cycle.

In some cases, test development may be aided by test templates that specify default parameters and hardware resources for conducting a test. Such is the case with the SmartTest Program Generator software that provides test development capabilities for the Agilent 93000 SOC Series tester (both of which are distributed by Agilent Technologies, Inc. of Palo Alto, Calif., USA).

### SUMMARY OF THE INVENTION

In one embodiment, a number of machine-readable media have stored thereon sequences of instructions that, when executed by a machine, cause the machine to perform actions comprising: 1) displaying an ATE test template selection tool; 2) upon user selection of a test template from the ATE test template selection tool, displaying default parameters of the selected test template; and 3) providing user access to a test template configuration tool that enables a user to configure at least one hardware resource specified by the test template.

In another embodiment, a number of machine-readable media have stored thereon sequences of instructions that, when executed by a machine, cause the machine to perform actions comprising: 1) displaying a test template configuration tool that enables a user to configure at least one hardware resource specified by a test template for ATE; and 2) upon a user's use of the tool to select one of the hardware resources, enabling the user to configure the selected hardware resource.

Other embodiments are also disclosed.

### BRIEF DESCRIPTION OF THE DRAWINGS

Illustrative embodiments of the invention are illustrated in the drawings, in which:

FIGS. 1 & 2 illustrate computer-implemented methods that provide for configuration of hardware resources specified in a test template; and

FIGS. 3-14 illustrate various states of a graphical user interface for implementing the methods shown in FIGS. 1 & 2.

### DETAILED DESCRIPTION

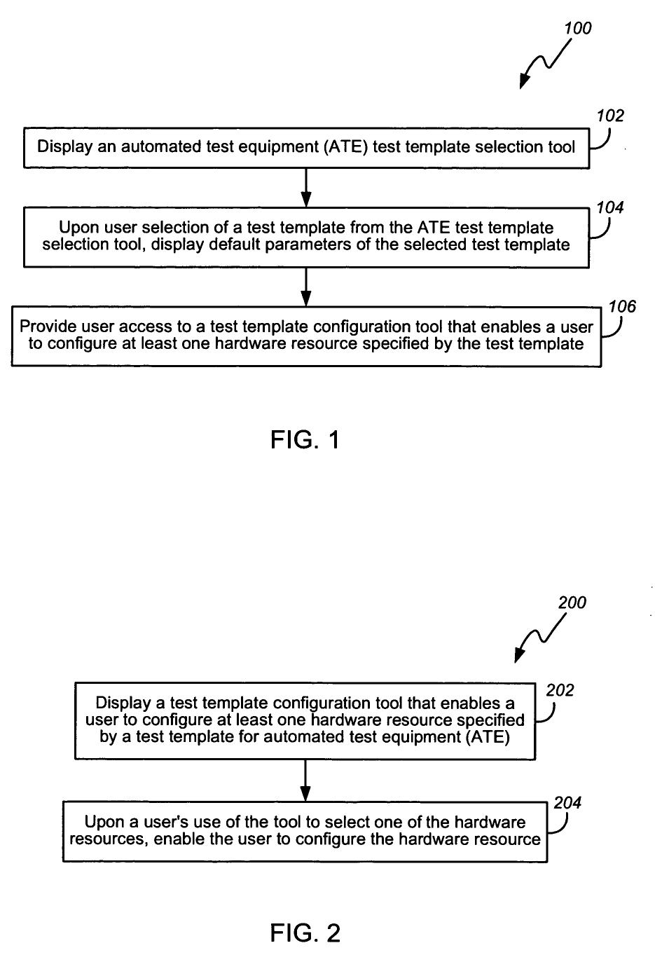

FIGS. 1 and 2 illustrate computer-implemented methods 100, 200 that provide for configuration of hardware resources specified in a test template. In accordance with the method 100, an automated test equipment (ATE) test template selection tool is displayed 102. Then, upon a user's selection of a test template from the ATE test template selection tool, default parameters of the selected test template are displayed 104. The user is then provided access 106 to a test template configuration tool that enables a user to configure the one or more hardware resources that are specified by the test template.

The method 200 presumes that a test template has already been selected. As a result, the method 200 begins with the display 202 of a test template configuration tool that enables a user to configure the one or more hardware resources that are specified by a test template. Then, upon a user's use of the tool to select one of the hardware resources, the user is enabled 204 to configure the selected hardware resource.

The methods 100 and 200 may be embodied in sequences of instructions stored on a number of machine-readable media (e.g., one or more fixed or removable memories or disks). When executed by a machine (e.g., a computer or computer network), the sequences of instructions cause the machine to perform the actions of the method 100 or 200.

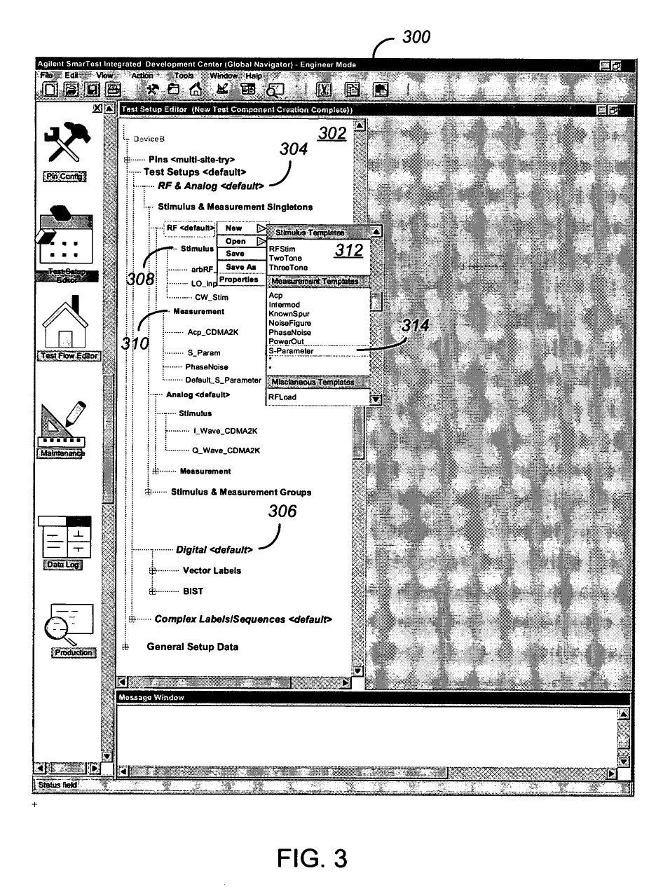

By way of example, FIGS. 3-14 illustrate various states of an exemplary graphical user interface (GUI 300) that may be displayed as a result of execution of sequences of instructions that implement the method 100 or 200 (as well as various modifications thereto).

As shown in FIG. 3, the GUI 300 provides access to a test setup tree view 302 and a test template selection tool 312. By way of example, the tree view 302 may provide a view of available test setups that include, for example, RF & Analog test setups 304 and Digital test setups 306. Within each group 304, 306 of test setups, the tree view may provide for further selection of either stimulus or measurement test setups 308, 310. Then, from a click activated tool 312 (e.g., a pop-up menu), available test templates may be displayed to a user. In the GUI view shown in FIG. 3, a test template 314 labeled “S-Parameter” has been highlighted for selection.

Preferably, a test template specifies default parameters and hardware resources that are sufficient to define an executable test. That is, execution of a stimulus test should bring a stimulus signal to at least one ATE pin, and execution of a measurement test should record a measurement for at least one ATE pin. In this manner, a user need not do anything but select a test template to configure a device test.

The parameters and hardware resources specified by a test template may specify physical and electrical parameters under which testing will occur, including, for example, indications of the ATE test paths and hardware resources that will be used during testing, as well as their configuration (including, e.g., identifications of stimulus and/or measurement paths, and indications of which ATE pins will be coupled to which pins of a device); indications of testing frequencies (including, e.g., a test frequency range); indications of modulation formats; indications of measurement bandwidths; or indications of power or voltage levels.

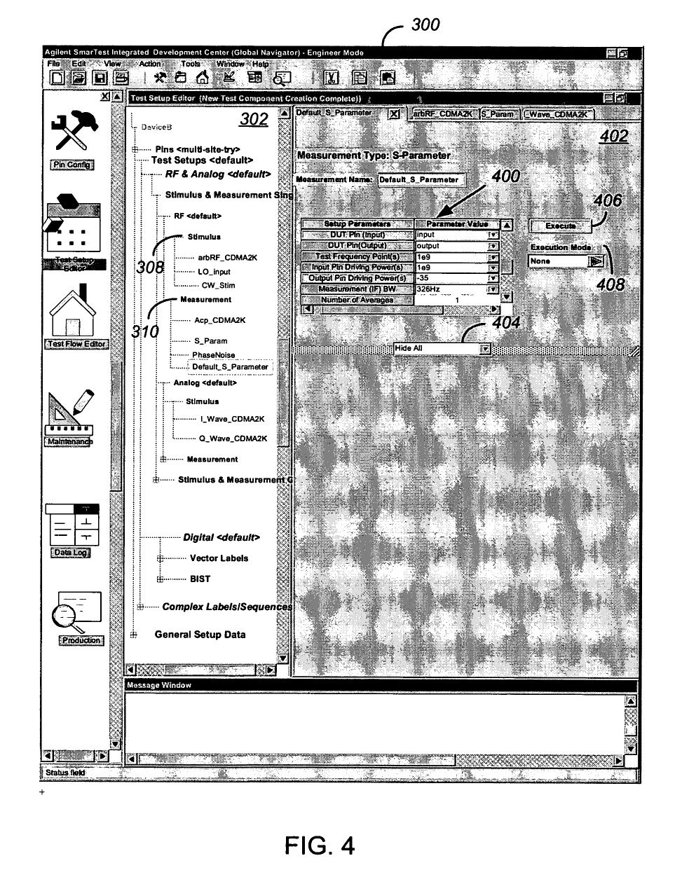

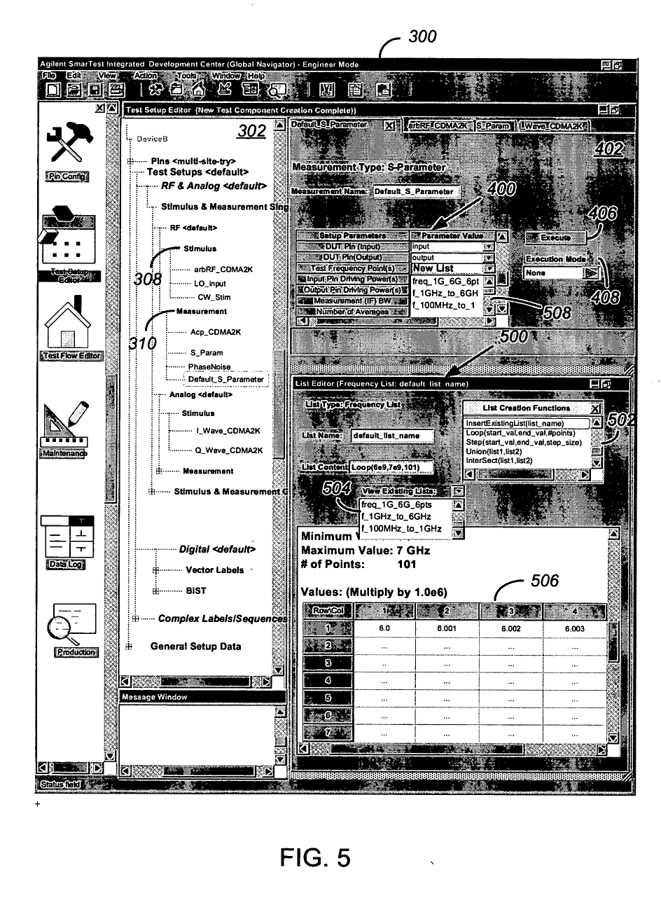

FIG. 4 illustrates the GUI 300 after a user has selected the exemplary “S-Parameter” test template 314. As shown, default parameters 400 of the test template 314 may be displayed in a right-hand window (or test template configuration tool 402) of the GUI 300. Preferably, the default parameters 400 are selectable and configurable by a user. In one embodiment, the user's selection of a parameter enables a user to select a new parameter from, for example, a pop-up, pull-down or scrolling menu of options 508. See FIG. 5. Alternately (or additionally), a user may be able to input (e.g., type in) a desired alternative. In another embodiment, the user's selection of the parameter, or the user's selection of a menu option that becomes selectable after the parameter is selected, may provide the user access to a parameter list editor 500, such as a frequency list editor. From within the parameter list editor 500, the user may optionally and variously 1) specify list creation functions 502 to help define a parameter list, 2) select from predefined parameter lists 504, and/or 3) manually provide parameters of a list using, for example, a parameter input table 506 provided by the editor 500.

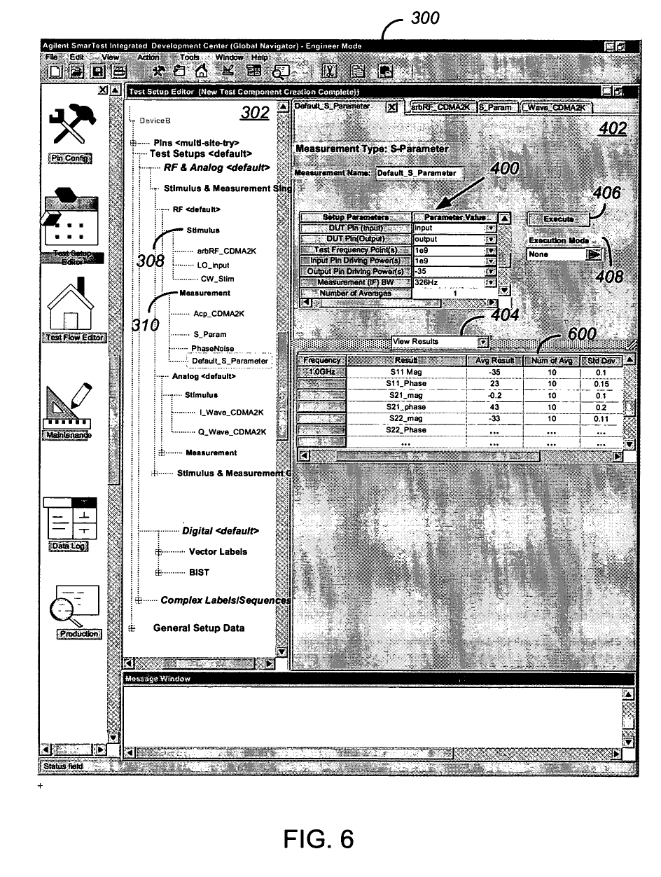

About halfway down the right-hand window 402, a tool selection mechanism 404 is provided. The mechanism 404 is exemplary only, and may provide access to various tools. FIG. 6 illustrates use of the selection mechanism 404 to display the results associated with execution of a test in accordance with the test template 314. Test execution may be triggered by pressing an “Execute” button 406. Optionally, an execution mode may first be selected from an execution mode selector 408. Upon execution of the test, test results may be displayed in a variety of preconfigured or programmable forms, including those of a table (e.g., table 600) or chart.

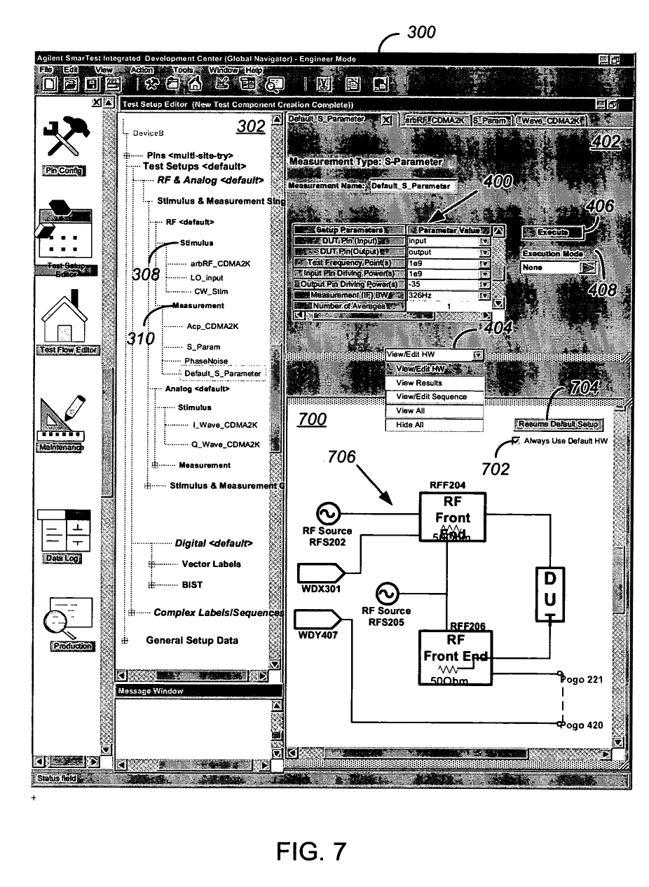

FIG. 7 illustrates an exemplary hardware and schematic configuration tool 700 for enabling a user to configure the hardware resources specified by a test template. In some cases, the tool 700 may be automatically launched upon a user's selection of a test template (e.g., the test template 314). In other cases, a user may have to launch the tool 700 by, for example, selecting it via the tool selection mechanism 404.

As shown in FIG. 7, the tool 700 may be provided with a means (e.g., the checkbox 702 next to the text “Always Use Default HW”) to prevent accidental changes to the default hardware displayed by the tool 700. The tool 700 may also be provided with a means (e.g., button 704) to restore a test template's default hardware setup.

Although the tool 700 may only display a hardware list, it preferably displays a schematic 706. The schematic 706 may show the hardware resources specified by a test template, as well as their connections. In one embodiment, the schematic 706 comprises a scalable vector graphic (SVG) image.

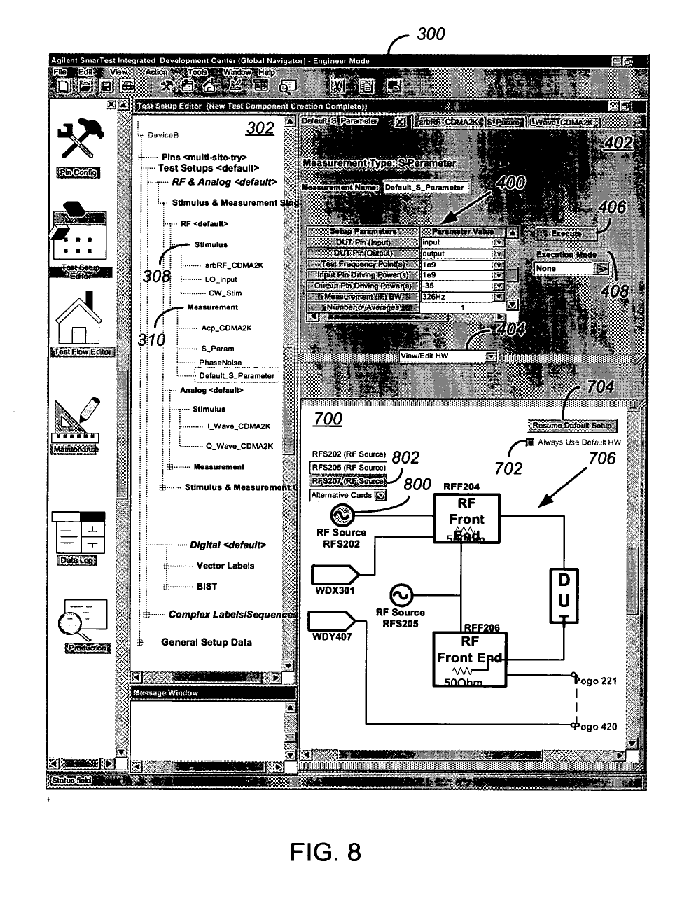

Upon a user's selection of a hardware resource (e.g., RF source 800; FIG. 8) from within the tool 700, the tool 700 displays one or more available alternate hardware resources from which a replacement hardware resource 802 may be selected. By way of example, the alternate hardware resource(s) may be displayed via a permanent or pop-up menu. In some cases, the tool 700 may provide a means to replace a default resource with multiple resources, or a means to specify a resource of which the tool 700 is not aware.

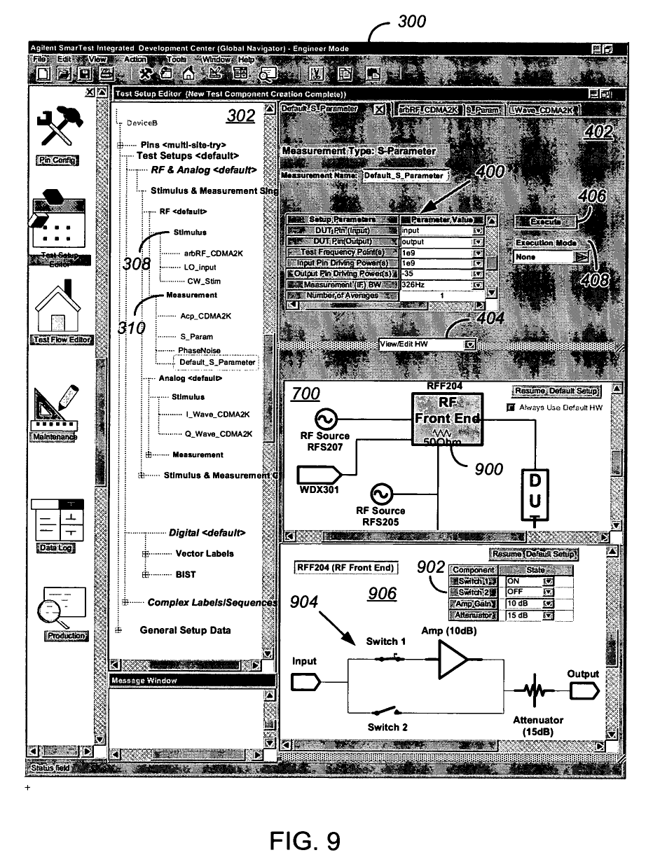

The tool 700 may also provide access to configurable settings 902 for a selected hardware resource 900. See FIG. 9. In one embodiment, upon user selection of a resource 900, the tool 700 provides 1) single mouse-click access (e.g., a right button mouse-click) to alternate hardware resources, and 2) double mouse-click access to configurable settings 902 for the hardware resource 900. As shown in FIG. 9, the configurable settings 902 may be displayed in table form along with a schematic of components 904 for the selected hardware resource 900.

Although not shown, a user's access of configurable settings for a resource may also cause the tool 700 to provide for user selection of program code for operating the selected hardware resource. For example, if a user selects a digitizer card, the user may be provided with a means for modifying the digital signal processor (DSP) algorithms used by the card, or a means for downloading/uploading a desired DSP algorithm.

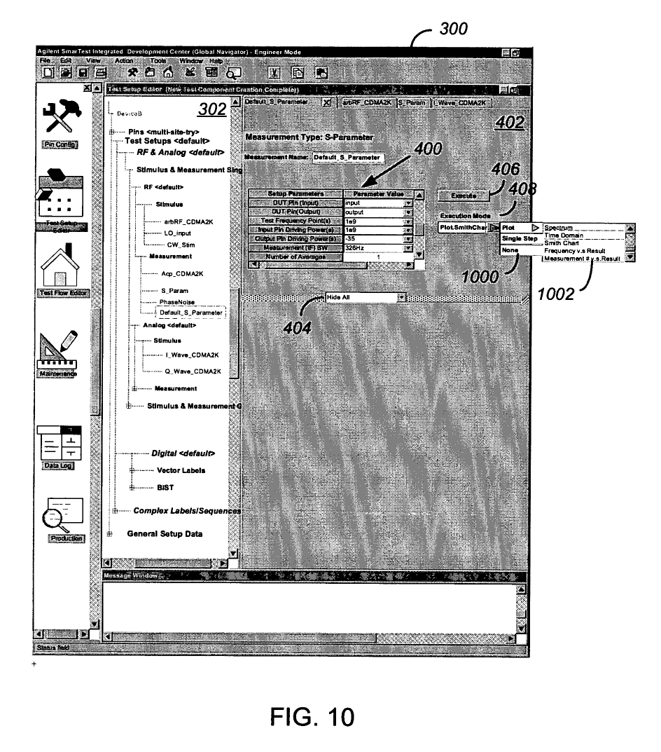

As previously mentioned, the GUI 300 may comprise an execution mode selector 408. FIG. 10 illustrates an exemplary pop-up menu 1000 that may be displayed upon a user's trigger of the execution mode selector 408. One of the available modes may be a plotting mode, in which case a second-tier pop-up menu 1002 may display types of plots that may be selected. For example, for the “S-Parameter” test template 314, the plot choice might be a “Smith Chart”. For a power measurement template, the plot choice might be a “Time Domain” or “Spectrum” plot. For measurement templates that utilize a frequency list, the plot choice might be “Frequency vs. Results”.

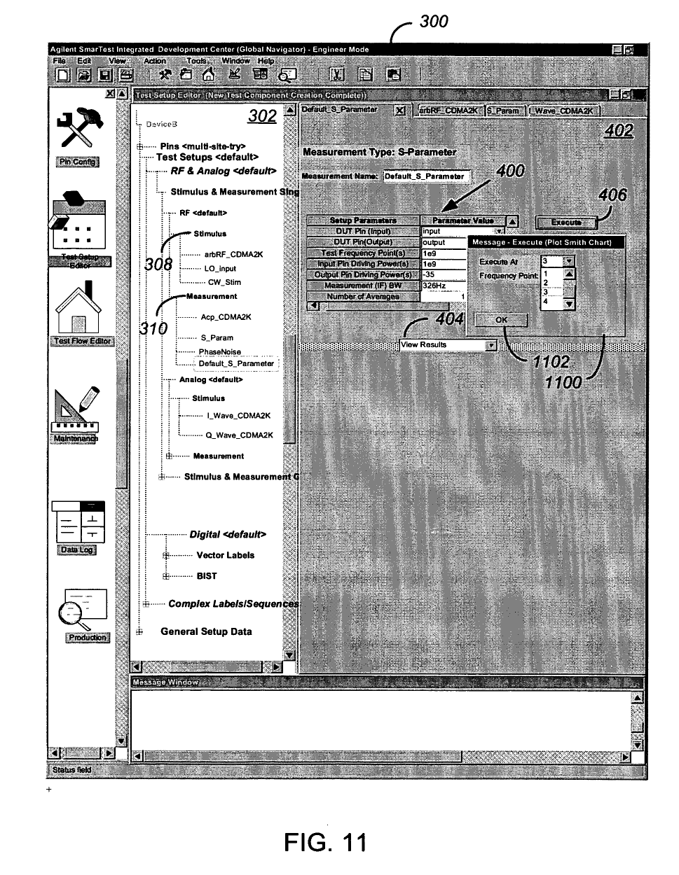

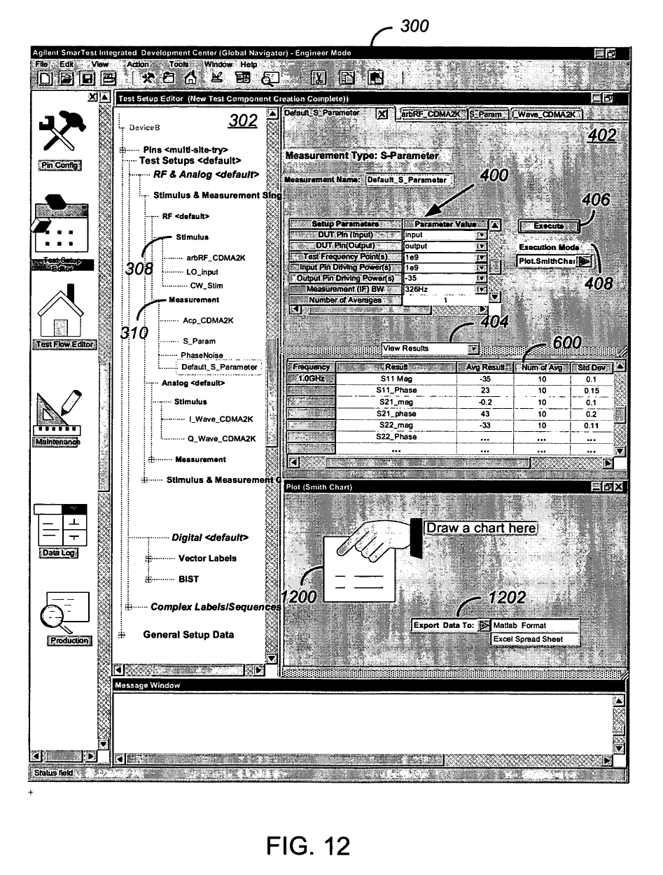

Selection of some of the plot types may trigger the display of a plot configuration tool 1100. See FIG. 11. Upon user confirmation of a plot configuration (e.g., by a press of an “OK” button 1102), or if no configuration is needed, upon the user's selection of a plotting mode, the GUI 300 may display a plot area 1200. See FIG. 12. Note, however, that execution of a test corresponding to the displayed test parameters 400 is required to obtain execution results for drawing a plot in the plot area. In one embodiment, the GUI 300 also provides access to a plot download function 1202 for exporting the data of the displayed plot 1200 to another process or application.

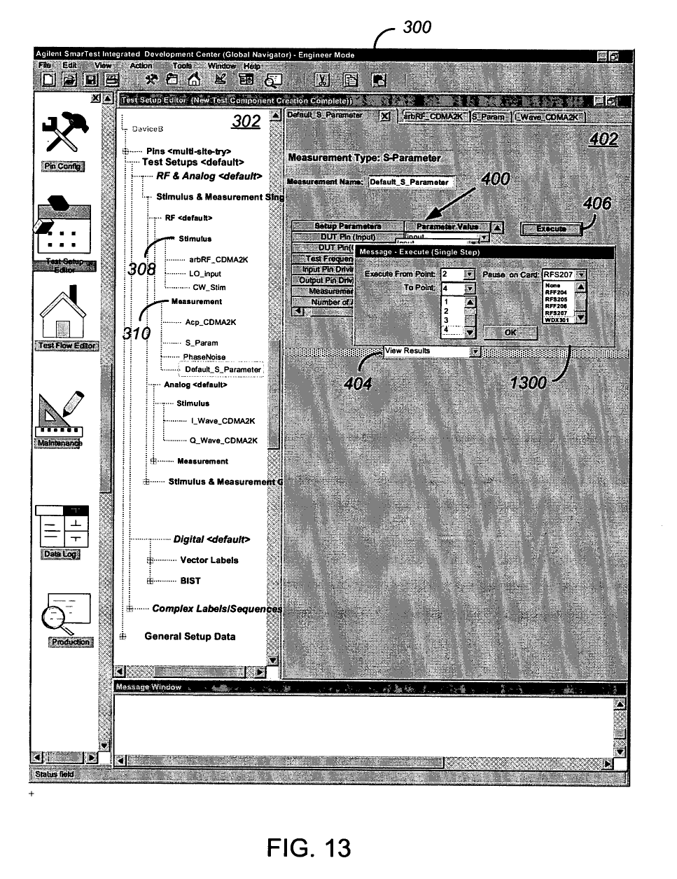

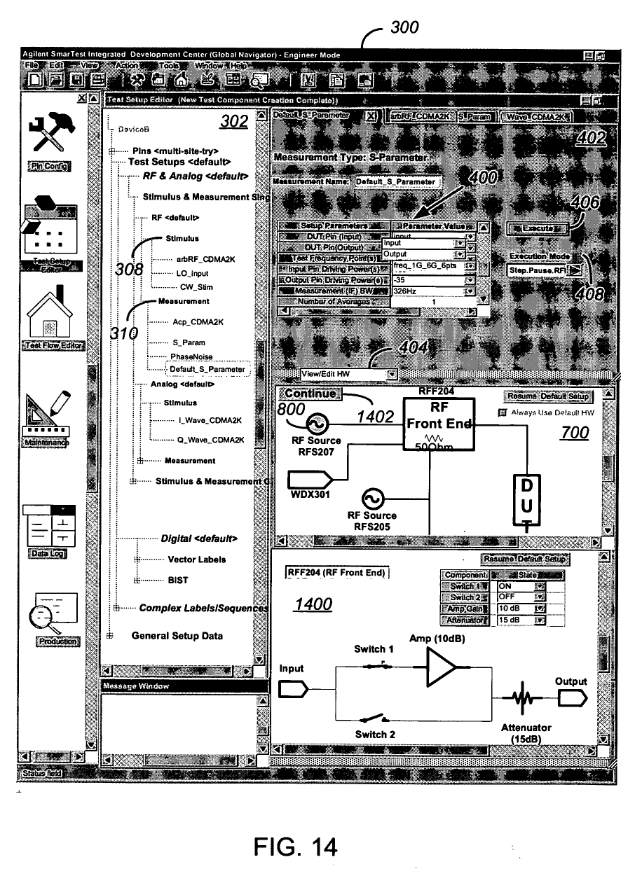

FIG. 13 illustrates a configuration tool 1300 for a stepped execution mode that may be selected using the execution mode selector 408. By way of example, the tool 1300 provides a means 1302 to select a range of frequencies over which a test is to be executed, as well as a means 1304 to select a hardware resource 800 for which settings are to be displayed at the end of a test execution step. FIG. 14 illustrates a display 1400 of the resource's settings during stepped execution. As shown, the display 1400 may enable a user to configure the selected hardware resource 800. A means for continuing a stepped execution (e.g., a “CONTINUE” button 1402) may be provided within the window 1400, within the window 700 (as shown), or near the “Execute” button 406.

The methods 100, 200 and apparatus 300 disclosed herein are useful in one respect in that they provide both high-level control (e.g., via the tree view 302, test template selection control 312, and test template configuration tool 402) and low-level control (e.g., via the test template hardware and schematic configuration tool 700) over ATE test setups. Further, access to the high and low-level controls 302, 402, 700 may be provided through a single GUI 300.

What is claimed is:

1. A number of machine-readable media having stored thereon sequences of instructions that, when executed by a machine, cause the machine to perform actions comprising:
displaying an automated test equipment (ATE) test template selection tool;
upon user selection of a test template from the ATE test template selection tool, displaying default parameters of the selected test template; and
providing user access to a test template configuration tool that enables a user to configure at least one hardware resource specified by the test template.

2. The media of claim 1, wherein the default parameters and specified hardware resource(s) associated with the test template are sufficient to define an executable test.

3. The media of claim 1, wherein the sequences of instructions further cause the machine to enable user selection and configuration of at least one of the displayed default parameters.

4. The media of claim 1, wherein upon user selection of one of the displayed default parameters, the sequences of instructions cause the machine to provide user access to a parameter list editor.

5. The media of claim 1, wherein the sequences of instructions cause the machine to provide user access to the test template configuration tool by automatically launching the tool upon selection of the test template.

6. The media of claim 1, wherein the user access to the test template configuration tool is provide via a tool selection mechanism.

7. The media of claim 1, wherein the test template configuration tool provides a schematic of specified hardware resources and their connections.

8. The media of claim 7, wherein the schematic comprises a scalable vector graphic (SVG) image.

9. The media of claim 1, wherein upon stepped execution of a test defined by the selected test template, the sequences of instructions cause the machine to display the settings of at least one hardware resource.

10. The media of claim 9, wherein the sequences of instructions cause the machine to enable user configuration of the hardware resource for which settings are displayed.

11. The media of claim 9, wherein the sequences of instructions further cause the machine to enable user selection of the hardware resource for which settings are displayed.

12. The media of claim 1, wherein upon user selection of a hardware resource from within the test template configuration tool, the tool displays at least one alternate hardware resource from which a replacement hardware resource may be selected.

13. The media of claim 1, wherein upon user selection of a hardware resource from within the test template configuration tool, the tool provides access to configurable settings for the hardware resource.

14. The media of claim 1, wherein the sequences of instructions further cause the machine to display an execution mode selector for user selection of an execution mode for the selected test template.

15. The media of claim 14, wherein upon user selection of a plotting mode from the execution mode selector, and upon execution of a test defined by the selected test template, the sequences of instructions cause the machine to display a plot of execution results for the displayed default parameters.

16. The media of claim 15, wherein the sequences of instructions further cause the machine to provide user access to a plot download function.

17. The media of claim 14, wherein upon user selection of a plotting mode from the execution mode selector, and upon execution of a test defined by the selected test template, the sequences of instructions cause the machine to perform actions comprising:
displaying a plot configuration tool; and
upon user confirmation of plot configuration, displaying a plot of execution results for the displayed default parameters.

18. A number of machine-readable media having stored thereon sequences of instructions that, when executed by a machine, cause the machine to perform actions comprising:
displaying a test template configuration tool that enables a user to configure at least one hardware resource specified by a test template for automated test equipment (ATE); and
upon a user's use of the tool to select one of the hardware resources, enabling the user to configure the selected hardware resource.

19. The media of claim 18, wherein the test template configuration tool provides a schematic of specified hardware resources and their connections.

20. The media of claim 19, wherein the schematic comprises a scalable vector graphic (SVG) image.

21. The media of claim 19, wherein upon stepped execution of a test defined by the selected test template, the sequences of instructions cause the machine to display the settings of at least one hardware resource.

22. The media of claim 21, wherein the sequences of instructions cause the machine to enable user configuration of the hardware resource for which settings are displayed.

23. The media of claim 21, wherein the sequences of instructions further cause the machine to enable user selection of the hardware resource for which settings are displayed.

24. The media of claim 18, wherein the test template configuration tool provides a list of specified hardware and their connections.

25. The media of claim 18, wherein upon user selection of a hardware resource from within the test template configuration tool, the tool displays at least one alternate hardware resource from which a replacement hardware resource may be selected.

26. The media of claim 18, wherein upon user selection of a hardware resource from within the test template configuration tool, the tool provides access to configurable settings for the hardware resource.

27. The media of claim 26, wherein upon user access of the configurable settings, the test template configuration tool displays a schematic of components for the selected hardware resource.

28. The media of claim 27, wherein the schematic of components for the selected hardware resource is displayed with a table of settings for different components of the schematic.

29. The media of claim 27, wherein upon user access of the configurable settings, the test template configuration tool provides for user selection of program code for operating the selected hardware resource.

30. The media of claim 18, wherein upon user selection of a hardware resource from within the test template configuration tool, the tool provides i) single mouse-click access to at least one alternate hardware resource from which a replacement hardware resource may be selected, and ii) double mouse-click access to configurable settings for the hardware resource.
